(19) United States
(12) Patent Application Publication
(10) Pub. No.: US 2013/0160702 A1
(43) Pub. Date: Jun. 27, 2013

(54) METHODS OF GROWING III-V SEMICONDUCTOR MATERIALS, AND RELATED SYSTEMS

(71) Applicant: Ed Lindow, Scottsdale, AZ (US)

(72) Inventor: Ed Lindow, Scottsdale, AZ (US)

(73) Assignee: SOITEC, Crolles Cedex (FR)

(21) Appl. No.: 13/336,829

(22) Filed: Dec. 23, 2011

(51) Int. Cl. C30B 25/10; C30B 25/02

(52) U.S. Cl. 117/103; 117/88

(57) ABSTRACT

Methods and systems are increase the number of Group V ions formed from Group V precursors in methods of forming III-V semiconductor materials to enhance the growth rate of the III-V semiconductor material. In some embodiments, a Group V precursor is heated and at least partially decomposed in a heated diffuser to form Group V ions. In additional embodiments, microwave energy is applied to a Group V precursor and the Group V precursor is at least partially decomposed to form Group V ions. Group III ions are also formed, and the Group III and Group V ions are used to form a III-V semiconductor material within a chamber.

### TECHNICAL FIELD

The present disclosure relates to methods of growing III-V semiconductor materials, and to systems and devices for performing such methods.

### BACKGROUND

III-V semiconductor materials are compound semiconductor materials comprised of one or more elements from group IIIA of the periodic table (B, Al, Ga, In, and Ti) and one or more elements from group VA of the periodic table (N, P, As, Sb, and Bi). For example, III-V semiconductor materials include, but are not limited to, GaN, GaP, GaAs, InN, InP, InAs, AlN, AlP, AlAs, InGaN, InGaP, GaInN, InGaNP, GaInNAs, etc. III-V semiconductor materials are used in a number of semiconductor devices and structures, such as light emitting diodes, laser diodes, photodiodes, solar cells, etc.

III-V semiconductor materials are relatively difficult and expensive to fabricate. Chemical vapor deposition processes are used to fabricate III-V semiconductor materials. Chemical vapor deposition (CVD) is a chemical process that is used to deposit a solid material, such as a III-V semiconductor material, on substrates. In CVD processes, a substrate is exposed to one or more reagent gases, which react, decompose, or both react and decompose in a manner that results in the deposition of the solid material on the surface of the substrate.

One particular type of CVD process is referred to in the art as vapor phase epitaxy (VPE). In VPE processes, a substrate is exposed to one or more reagent vapors in a reaction chamber, which react, decompose, or both react and decompose in a manner that results in the epitaxial deposition of a solid material on the surface of the substrate. VPE processes are often used to deposit III-V semiconductor materials. When one of the reagent vapors in a VPE process comprises a halide vapor, the process may be referred to as a halide vapor phase epitaxy (HVPE) process.

It is known in the art to form III-nitride semiconductor materials, such as gallium nitride (GaN) and indium gallium nitride (InGaN), using VPE processes in which metalorganic (MO) precursor materials are decomposed within a reaction chamber to form the III-nitride semiconductor material. Such processes are often referred to as metalorganic vapor phase epitaxy (MOVPE) processes, and may also be characterized as metalorganic chemical vapor deposition (MOCVD) processes.

### BRIEF SUMMARY

This summary is provided to introduce a selection of concepts in a simplified form. These concepts are described in further detail in the detailed description of example embodiments of the disclosure below. This summary is not intended to identify key features or essential features of the claimed subject matter, nor is it intended to be used to limit the scope of the claimed subject matter.

In some embodiments, the present disclosure includes methods of forming III-V semiconductor material. A Group V precursor may be heated and at least partially decomposed in a heated diffuser to form Group V ions. A Group III precursor may be at least partially decomposed to form Group III ions, and a III-V semiconductor material may be formed from the Group V ions and the Group III ions within a chamber.

In additional embodiments, the present disclosure includes methods of forming III-V semiconductor material in which microwave energy is applied to a Group V precursor to decompose the Group V precursor and form Group V ions. A Group III precursor is also decomposed to form Group III ions, and a III-V semiconductor material is formed in a chamber from the Group V ions and the Group III ions.

In yet further embodiments, III-V semiconductor material may be formed by applying microwave energy to a Group V precursor and heating the Group V precursor to at least partially decompose the Group V precursor to form Group V ions, decomposing a Group III precursor to form Group III ions, and fanning a III-V semiconductor material in a chamber from the Group V ions and the Group III ions.

Additional embodiments of the disclosure include semiconductor structures and devices fabricated using such methods, as well as deposition systems that may be used to perform such methods.

### BRIEF DESCRIPTION OF THE DRAWINGS

While the specification concludes with claims particularly pointing out and distinctly claiming what are regarded as embodiments of the invention, the advantages of embodiments of the disclosure may be more readily ascertained from the description of certain examples of embodiments of the disclosure when read in conjunction with the accompanying drawings, in which:

FIG. 1 is a simplified, schematic cross-sectional view of an embodiment of a chemical vapor deposition system that may be employed to perform methods as described herein;

FIG. 2 is a simplified, schematic cross-sectional view of another embodiment of a chemical vapor deposition system that may be employed to perform methods as described herein; and

FIG. 3 is a simplified, schematic cross-sectional view of another embodiment of a chemical vapor deposition system that may be employed to perform methods as described herein.

### DETAILED DESCRIPTION

The illustrations presented herein are not meant to be actual views of any particular semiconductor material, structure, device, or method, but are merely idealized representations that are used to describe embodiments of the disclosure.

Any headings used herein should not be considered to limit the scope of embodiments of the invention as defined by the claims below and their legal equivalents. Concepts described in any specific heading are generally applicable in other sections throughout the entire specification.

A number of references are cited herein, the entire disclosures of which are incorporated herein in their entirety by this reference for all purposes. Further, none of the cited references, regardless of how characterized herein, is admitted as prior art relative to the invention of the subject matter claimed herein.

As used herein, the term “III-V semiconductor material” means and includes any semiconductor material that is at least predominantly comprised of one or more elements from group IIIA of the periodic table (B, Al, Ga, In, and Ti) and one or more elements from group VA of the periodic table (N, P, As, Sb, and Bi). For example, III-V semiconductor materials include, but are not limited to, GaN, GaP, GaAs, InN, InP, InAs, AlN, AlP, AlAs, InGaN, InGaP, GaInN, InGaNP, GaInNAs, etc.

Embodiments of methods disclosed herein may be employed to form III-V semiconductor material, which may be used in the fabrication of semiconductor devices. Embodiments of the present invention may be employed to increase growth rates of certain III-V semiconductor materials, such as InGaN, by increasing a quantity of reactive Group V ions present and available for reactive combination with Group III ions at a surface of a substrate on which III-V semiconductor material is to be deposited. In some embodiments, the methods include heating and at least partially decomposing a Group V precursor in a heated diffuser to form Group V ions prior to providing the precursor in the immediate vicinity of the surface on which the III-V material is to be deposited. In additional embodiments, the methods include applying microwave energy to a Group V precursor and at least partially decomposing the Group V precursor to form Group V ions prior to providing the precursor in the immediate vicinity of the surface on which the III-V material is to be deposited. Yet further embodiments include combinations of such processes. Example embodiments of such methods are disclosed below.

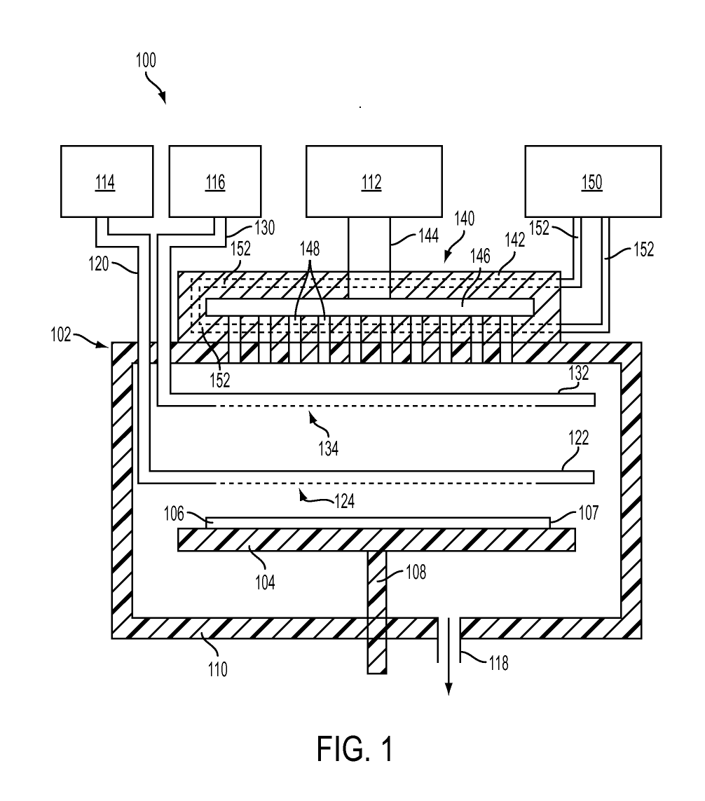

FIG. 1 is a simplified schematic diagram of a cross-section of a deposition system 100. The deposition system 100 may comprise a chemical vapor deposition (CVD) system, such as a vapor phase epitaxy (VPE) system, a halide vapor phase epitaxy (HVPE) system, or a metalorganic chemical vapor deposition (MOCVD) system.

The deposition system 100 includes a deposition chamber 102, in which the pressure and temperature may be selectively controlled. A substrate support structure 104, which may comprise a susceptor, is disposed within the chamber 102. The substrate support structure 104 is sized, shaped, and configured to support a workpiece substrate 106 thereon, on which III-V semiconductor material is to be deposited using the deposition system 100. The substrate support structure 104 may be supported by a spindle 108, which may be rotated to drive rotation of the substrate support structure 104 and a workpiece substrate 106 thereon during a deposition process.

Although not shown in FIG. 1, the deposition system 100 may comprise one or more heating elements for heating the substrate support structure 104 (and any workpiece substrate 106 thereon) and/or the interior of the deposition chamber 102. In some embodiments, radiation may be sued to heat the substrate support structure 104 (and any workpiece substrate 106 thereon). In such embodiments, a radiation source may be positioned outside the deposition chamber 102 and configured to emit radiation into the deposition chamber 102 and onto the substrate support structure 104 (and any workpiece substrate 106 thereon). In such embodiments, the walls 110 of the deposition chamber 102 may comprise a material such as quartz that is at least substantially transparent to the radiation, and the substrate support structure 104 may comprise a material configured to absorb the radiation, such that the substrate support structure 104 is heated by the thermal radiation. The substrate support structure 104 and any workpiece substrate 106 thereon may be capable of being heated to temperatures from about 500° C. to about 1200° C. during deposition processes, depending on the nature of the workpiece substrate 106 and the III-V semiconductor material to be deposited thereon.

The deposition system 100 further includes a gas flow system used to flow process gases through the deposition chamber 102. The gas flow system may include at least one source 112 of a Group V precursor, at least one source 114 of a Group III precursor, and at least one source 116 of a carrier gas and/or an inert gas.

Various conduits and/or devices may be used to flow the various process gases from the sources 112, 114, 116 into the deposition chamber 102.

As shown in FIG. 1, one or more conduits 120 may be used to convey a Group III precursor from the source 114 into the deposition chamber 102. The conduits 120 may be configured to inject the Group III precursor into the interior region of the deposition chamber 102 at a location proximate an exposed major surface 107 of the workpiece substrate 106. For example, the conduits 120 may lead to a gas diffuser 122, which may include a plurality of apertures 124 through which the Group III precursor (or decomposition products thereof, such as Group III ions) are introduced into the interior region of the deposition chamber 102 (although the diffuser 124 itself may be disposed within the interior region of the deposition chamber 102, partially within the interior region of the deposition chamber 102, or outside and adjacent the deposition chamber 102).

Similarly, one or more conduits 130 may be used to convey a carrier gas and/or an inert gas from the source 116 into the deposition chamber 102. The conduits 130 may lead to a gas diffuser 132, which may include a plurality of apertures 134 through which the carrier gas and/or inert gas are introduced into the interior region of the deposition chamber 102 (although the diffuser 134 itself may be disposed within the interior region of the deposition chamber 102, partially within the interior region of the deposition chamber 102, or outside and adjacent the deposition chamber 102).

The deposition system 100 further includes at least one heated diffuser 140 configured to heat and at least partially decompose a Group V precursor supplied from the source 112 and provide Group V ions to be introduced into the deposition chamber 102. As shown in FIG. 1, a Group V precursor may flow from the source 112 through a conduit 144 to the heated diffuser 140. The heated diffuser 140 includes a body 142, which may comprise a metal, such as a steel alloy. The body 142 may include at least one inner cavity 146 into which the Group V precursor may be caused to flow from the conduit 144. The body 142 may further include one or more apertures 148 extending from the inner cavity 146 to the exterior of the body 142. Fluid communication may be provided between the apertures 148 and the interior of the deposition chamber 102, such that the Group V precursor (and/or decomposition products thereof, such as Group V ions) may be caused to flow from the inner cavity 146 through the apertures 148 and into the interior region of the deposition chamber 102.

In some embodiments, the heated diffuser 140 may comprise a catalyst material configured to catalyze decomposition of a Group V precursor. For example, ruthenium, nickel, rhodium, cobalt, iridium, iron, platinum, chromium, palladium, copper, and tellurium are known to be catalysts that are capable of catalyzing the decomposition of ammonia (NH₃), which may be used as a Group V precursor. See e.g., S. Stolbov and T. S. Rahman, First Principles Study of Adsorption, Diffusion and Dissociation of NH3 on Ni and Pd Surfaces, Department of Physics, Cardwell Hall, Kansas State University, (Manhattan, Kan. 55606, U.S.A. (arXiv:cond-mat/0501060v1, submitted Jan. 5, 2005), which is incorporated herein in its entirety by this reference. Thus, in some embodiments, the body 142 of the heated diffuser 132 may be formed from and comprise a metal or metal alloy including one or more elements capable of catalyzing decomposition of a Group V precursor, such as those set forth above. By way of example and not limitation, the body 142 may comprise an iron-based alloy, such as a steel alloy. The alloy may further include one or more of ruthenium, nickel, rhodium, cobalt, iridium, platinum, chromium, palladium, copper, and tellurium. Furthermore, the inner surfaces of the body 142 within the inner cavity 146, the conduit 144, and/or the apertures 148, may be roughened or otherwise textured so as to provide surface discontinuities, which may contribute to increased catalytic decomposition of the Group V precursor.

In some embodiments, the heated diffuser 140 may be heated by flowing heated fluid (e.g., a liquid) through the body 142 of the diffuser 140. The heated fluid flowing through the heated diffuser 140 may be isolated from the Group V precursor flowing through the diffuser 140. As shown in FIG. 1, the deposition system 100 may include a source 150 of heated fluid. The source 150 may comprise, for example, a reservoir in which fluid may be heated, and a pump for pumping the fluid from the reservoir, through the body 142 of the heated diffuser 140, and back to the reservoir. As shown in FIG. 1, a conduit 152 may extend from the source 150 of heated fluid, into and through the body 142 of the heated diffuser 140, and back to the source 150 so as to provide a circuit of flowing heated fluid.

The heated fluid may comprise an oil. In some embodiments, the heated fluid may comprise a fulminated liquid, such as that known as FLUORINERT and commercially available from 3M of St. Paul, Minn.

The heated fluid may be used to heat the heated diffuser 140 and the Group V precursor flowing there through to a temperature between about 60° C. and about 215° C., at which temperature the heated Group V precursor may be injected into the interior of the chamber 102.

The gas flow system of the deposition system 100 further includes an exhaust system for evacuating the process gases out from the interior of the deposition chamber 100 through at least one exhaust portion 118. A vacuum system (not shown) may be coupled to the exhaust port 118 and used to provide a vacuum within the deposition chamber 102 and to draw the process gases into a vacuum from the deposition chamber 102 through the exhaust port 118. Thus, during a deposition process, various process gases may be caused to flow at respective selected and controlled flow rates from the various process gas sources 112, 114, 116 through the interior region of the deposition chamber 102, over the surface 107 of the workpiece substrate 106 (whereon III-V semiconductor material is deposited), and out from the deposition chamber 102 through the exhaust portion 118.

The deposition system 100 described above may be used to form a III-V semiconductor material. A Group V precursor supplied from the source 112 may be heated in the heated diffuser 140. As the Group V precursor is heated in the heated diffuser 140, at least some of the Group V precursor may decompose to form Group V ions. A Group III precursor supplied from the source 114 also may be at least partially decomposed to form Group III ions, and a III-V semiconductor material may be formed on the surface 107 of the workpiece substrate 106 from the Group V ions and the Group III ions within the chamber 102.

The Group V precursor may comprise a nitrogen-containing precursor, such as ammonia (NH₃) or nitrogen (N₂).

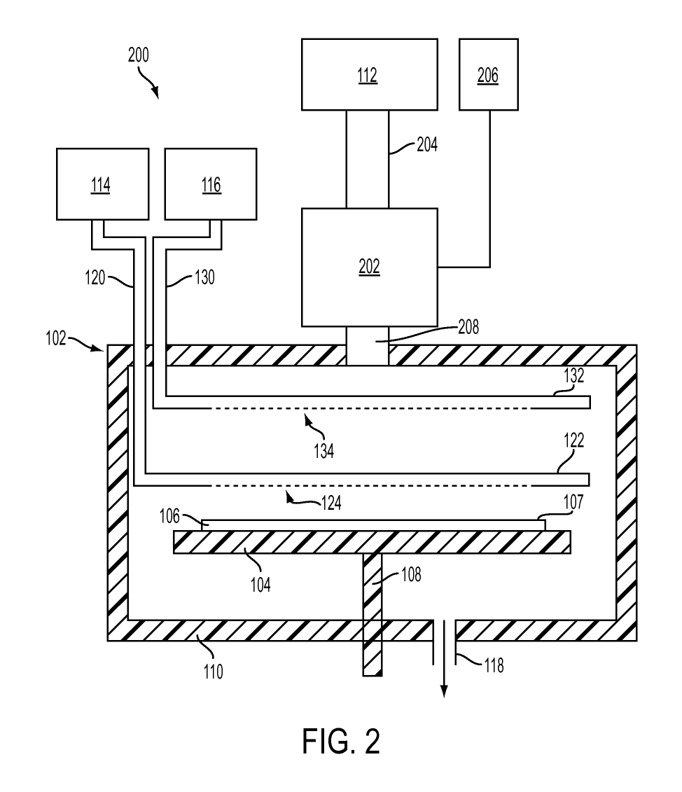

FIG. 2 illustrates another example embodiment of a deposition system 200 that may be used to fabricate III-V semiconductor material. The deposition system 200 is similar to the deposition system 100 of FIG. 1 in that the deposition system 200 also includes a deposition chamber 102, a substrate support structure 104 for supporting a workpiece substrate 106 thereon, a spindle 108, a source 112 of Group V precursor, a source 114 of Group III precursor, and a source 116 of carrier gas and/or inert gas. A conduit 120 may be used to convey Group III precursor from the source 114 to a diffuser 122 through which the Group III precursor may be injected into the interior region within the chamber 102. Similarly, a conduit 130 may be used to convey a carrier gas and/or an inert gas from the source 116 to a diffuser 132 through which the carrier gas and/or inert gas may be injected into the interior region within the chamber 102. The deposition system 200 may further include an exhaust port 118 through which a vacuum system may be used to draw process gases out from within the chamber 102.

The deposition system 200 further includes an ionization device 202 in which microwave energy may be applied to the Group V precursor supplied from the source 112 to decompose the Group V precursor to form Group V ions. A conduit 204 may be used to convey Group V precursor from the source 112 to the ionization device 202, and a conduit 208 may be used to convey the Group V ions from the ionization device 202 to the interior region within the deposition chamber 102.

In some embodiments, the ionization device 202 may comprise an enclosure in which microwave energy may be used to generate a plasma, and, as the Group V precursor flows into the enclosure and through the plasma, the Group V precursor is at least partially decomposed to form Group V ions. In some embodiments, the Group V precursor may be at least partially decomposed to form Group V ions and Group V radicals in the ionization device 202. The microwave energy and plasma may be generated and provided within the enclosure of the ionization device 202 without providing the microwave energy and plasma within the interior region of the deposition chamber 102 outside the enclosure of the ionization device 202. Thus, the Group III precursor supplied from the source 114 is not subjected to the microwave energy or the plasma generated within the ionization device 202.

By way of example and not limitation, the ionization device 202 may comprise a TWR 3000 Microwave Radical Generator, commercially available from R³T GmbH of Taufkirchen, Germany. A power supply 206 may be used to supply power to the ionization device 202 to allow the generation of the microwave energy and the plasma therein.

In some embodiments, the ionization device 202 may be disposed entirely outside the deposition chamber 102. The ionization device may be mounted directly on the deposition chamber 102 so as to reduce recombination of ions and radicals prior to reaching the surface 107 of the workpiece substrate 106. In other embodiments, the ionization device 202 may be disposed at least partially within the deposition chamber 102 so as to further reduce a distance between the ionization device 202 and the workpiece substrate 106.

The deposition system 200, like the deposition system 100 of FIG. 1, may be used to form a III-V semiconductor material. Microwave energy may be applied to a Group V precursor supplied from the source 112 in the ionization device 202 to form Group V ions. A Group III precursor supplied from the source 114 also may be at least partially decomposed to form Group III ions, and a III-V semiconductor material may be formed on the surface 107 of the workpiece substrate 106 from the Group V ions and the Group III ions within the chamber 102.

The Group V precursor may comprise a nitrogen-containing precursor, such as ammonia (NH₃). In additional embodiments, the Group V precursor may comprise nitrogen (N₂). It may be desirable to form nitrogen ions and radicals from N₂, as hydrogen is not a byproduct in the decomposition of N₂. Hydrogen can act as an etchant to materials of the workpiece substrate 106, and, in some applications, it may be desirable to avoid generating hydrogen as a byproduct of the decomposition of the Group V precursor.

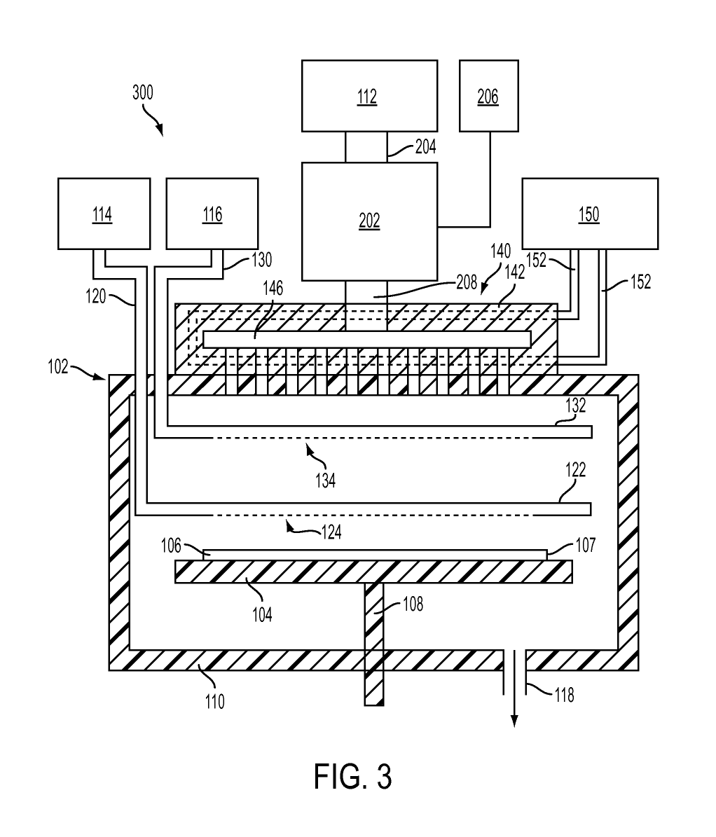

FIG. 3 illustrates another example embodiment of a deposition system 300 that may be used to fabricate III-V semiconductor material. The deposition system 300 is similar to the deposition system 100 (FIG. 1)and the deposition system 200 (FIG. 2), but includes both an ionization device 202 as described with reference to FIG. 2 and a heated diffuser 140 as described with reference to FIG. 1.

A conduit 204 may convey Group V precursor from the source 112 to the ionization device 202, and a conduit 208 may convey the Group V precursor (and/or decomposition products of the Group V precursor, such as ions and radicals) to the heated diffuser 140. The Group V precursor and/or decomposition products thereof may flow through the heated diffuser 140 and into the interior region within the deposition chamber 102. The use of the ionization device 202 and the heated diffuser 140 together may further increase the number of reactive ions and/or radicals available at the surface 107 of the substrate 106 to form III-V semiconductor material.

The deposition system 300 also includes a deposition chamber 102, a substrate support structure 104 for supporting a workpiece substrate 106 thereon, a spindle 108, a source 112 of Group V precursor, a source 114 of Group III precursor, and a source 116 of carrier gas and/or inert gas. A conduit 120 may be used to convey Group III precursor from the source 114 to a diffuser 122 through which the Group III precursor may be injected into the interior region within the chamber 102. Similarly, a conduit 130 may be used to convey a carrier gas and/or an inert gas from the source 116 to a diffuser 132 through which the carrier gas and/or inert gas may be injected into the interior region within the chamber 102. The deposition system 200 may further include an exhaust port 118 through which a vacuum system may be used to draw process gases out from within the chamber 102.

As previously mentioned, the Group V precursor may comprise a nitrogen-containing precursor, such as ammonia (NH₃) or nitrogen (N₂).

As a non-limiting example, the III-V semiconductor material fabricated using methods and systems as described herein may comprise InGaN. The InGaN may comprise InₓGa_{y}N, wherein x+y is at least substantially equal to one (1), and wherein x is between about 0.05 and about 0.15. In such embodiments, the Group III precursor may comprise both a gallium-containing precursor and an indium-containing precursor.

InGaN has previously been grown at temperatures lower than those often used to grow GaN. For example, GaN is often fabricated at temperatures of about 1,000° C. or more, whereas InGaN is often fabricated at temperatures less than 1,000° C. (e.g., about 800° C. for In_{0.08}Ga_{0.92}N). In such methods of growing InGaN, the growth rate of the InGaN is relatively lower than that of the growth rate of GaN formed at the relatively higher temperatures. For example the growth rate of InGaN in such methods may be from about 0.1 Angstroms per second to about 0.3 Angstroms per second, whereas the growth rate of GaN may be from about 3.0 Angstroms per second to about 55 Angstroms per second. The difference in growth rate may be attributable to less decomposition of the Group V precursor (e.g., NH₃) at the relatively lower temperatures at which InGaN is formed, which would result in less Group V ions (e.g., N ions) being available at the surface 107 of the workpiece substrate 106 for the formation of III-V semiconductor material. In other words, inefficient “cracking” of the Group V precursor limits the concentration of active Group V ions over the workpiece substrate 106. The limited number of Group V ions may require that the III-V semiconductor material (e.g., InGaN) be grown at relatively low growth rates to achieve a layer of III-V semiconductor material with an acceptable level of defects in the crystal structure (e.g., nitrogen or other Group V element vacancies).

Embodiments of methods and systems disclosed herein may provide an increased number of Group V ions at the surface 107 of the substrate 106 at a given deposition temperature by increasing the number of molecules of the Group V precursor that are decomposed during the deposition process, thereby allowing the III-V semiconductor material to be fabricated at relatively higher growth rates and while maintaining a relatively low concentration of defects in the crystal structure of the III-V semiconductor material being formed. By way of example and not limitation, in some embodiments, the III-V semiconductor material (e.g., InGaN) may be grown at a growth rate of at least about 1.0 Angstrom per second, or may be grown at a growth rate of at least about 5.0 Angstroms per second, or even may be grown at a growth rate of at least about 10.0 Angstroms per second. Further, the growth may be performed at temperatures of about 1,000° C. or less, about 900° C. or less, or even about 800° C. or less in some embodiments. Additionally, the III-V semiconductor grown under such conditions may have about a defect concentration therein of about 1×10⁹ /cm² or less, about 1×10⁸ /cm² or less, or even about 1×10⁷ /cm² or less in some embodiments. In some embodiments, this defect density may be at least substantially equal to, or less than, a defect density in the underlying material of the workpiece substrate 106 (e.g., GaN), such that no additional defects are introduced by way of growing the additional III-V semiconductor material (e.g., InGaN). Additionally, the III-V semiconductor material (e.g., InGaN) formed using methods as disclosed herein may be formed to comprise a layer of the III-V semiconductor material, and such a layer may have an average layer thickness of at least about 0.5 micron, at least about 1.0 microns, or even 5.0 microns or more, in some embodiments.

Additional non-limiting example embodiments of the disclosure are set forth below.

### EMBODIMENT 1

A method of forming InGaN, comprising: heating and at least partially decomposing at least one nitrogen-containing precursor in a heated diffuser to form nitrogen ions; at least partially decomposing at least one Group III precursor to form indium ions and gallium ions; and forming InGaN from the nitrogen ions, the indium ions, and the gallium ions within a chamber at a growth rate of at least about 1.0 Angstroms per second.

### EMBODIMENT 2

The method of Embodiment 1, wherein heating and at least partially decomposing the at least one nitrogen-containing precursor in the heated diffuser comprises flowing the at least one nitrogen-containing precursor through a heated diffuser comprising a metal.

### EMBODIMENT 3

The method of Embodiment 2, wherein flowing the at least one nitrogen-containing precursor through the heated diffuser comprising the metal comprises flowing the at least one nitrogen-containing precursor through a heated steel diffuser.

### EMBODIMENT 4

The method of Embodiment 2 or Embodiment 3, wherein flowing the at least one nitrogen-containing precursor through the heated diffuser comprising the metal comprises exposing the at least one nitrogen-containing precursor to at least one catalyst and catalyzing decomposition of the at least one nitrogen-containing precursor within the heated diffuser.

### EMBODIMENT 5

The method of Embodiment 4, wherein exposing the at least one nitrogen-containing precursor to the at least one metal catalyst comprises exposing the at least one nitrogen-containing precursor to at least one of nickel and iron.

### EMBODIMENT 6

The method of any one of Embodiments 1 through 5, further comprising flowing heated fluid through the diffuser to heat the diffuser.

### EMBODIMENT 7

The method of Embodiment 6, further comprising isolating the at least one nitrogen-containing precursor from the heated fluid flowing through the diffuser.

### EMBODIMENT 8

The method of Embodiment 6 or Embodiment 7, wherein flowing heated fluid through the diffuser comprises flowing oil through the diffuser.

### EMBODIMENT 9

The method of Embodiment 6 or Embodiment 7, wherein flowing heated fluid through the diffuser comprises flowing fluorinated liquid through the diffuser.

### EMBODIMENT 10

The method of any one of Embodiments 1 through 9, wherein heating and at least partially decomposing the at least one nitrogen-containing precursor in the heated diffuser comprises heating the at least one nitrogen-containing precursor in the heated diffuser to a temperature between about 60° C. and about 215° C. and injecting the heated at least one nitrogen-containing precursor into the chamber at the temperature between about 60° C. and about 215° C.

### EMBODIMENT 11

The method of any one of Embodiments 1 through 10, further comprising selecting the at least one nitrogen-containing precursor to comprise ammonia.

### EMBODIMENT 12

The method of any one of Embodiments 1 through 11, further comprising selecting the at least one Group III precursor to comprise a first gallium-containing precursor and a second indium-containing precursor.

### EMBODIMENT 13

The method of any one of Embodiments 1 through 12, wherein forming InGaN comprises forming InₓGa_{y}N, wherein x+y is about equal to 1, and wherein x is between about 0.05 and about 0.15.

### EMBODIMENT 14

The method of any one of Embodiments 1 through 13, wherein forming InGaN comprises growing the InGaN on a substrate within the chamber at a growth rate of at least about 5.0 Angstroms per second.

### EMBODIMENT 15

The method of any one of Embodiments 1 through 14, wherein forming InGaN comprises forming the InGaN on GaN.

### EMBODIMENT 16

The method of Embodiment 15, wherein forming InGaN further comprises forming the InGaN to have a defect density at least substantially equal to or less than a defect density of the GaN.

### EMBODIMENT 17

The method of any one of Embodiments 1 through 16, wherein forming InGaN comprises forming a layer of InGaN having an average layer thickness of at least about 0.5 micron.

### EMBODIMENT 18

A method of forming InGaN, comprising: applying microwave energy to at least one nitrogen-containing precursor and decomposing the at least one nitrogen-containing precursor to form nitrogen ions; decomposing at least one Group III precursor to form indium ions and gallium ions; and forming InGaN in a chamber from the nitrogen ions, the indium ions, and the gallium ions at a growth rate of at least about 1.0 Angstroms per second.

### EMBODIMENT 19

The method of Embodiment 18, wherein applying microwave energy to the at least one nitrogen-containing precursor and decomposing the at least one nitrogen-containing precursor to form nitrogen ions comprises forming nitrogen radicals.

### EMBODIMENT 20

The method of Embodiment 18 or Embodiment 19, further comprising applying the microwave energy to the at least one nitrogen-containing precursor without applying the microwave energy to the at least one Group III precursor.

### EMBODIMENT 21

The method of any one of Embodiments 18 through 20, wherein applying microwave energy to the at least one nitrogen-containing precursor comprises generating a plasma in an enclosure separate from the chamber using the microwave energy, and passing the at least one nitrogen-containing precursor through the enclosure.

### EMBODIMENT 22

The method of any one of Embodiments 18 through 21, further comprising selecting the at least one nitrogen-containing precursor to comprise ammonia.

### EMBODIMENT 23

The method of any one of Embodiments 18 through 22, further comprising selecting the at least one Group III precursor to comprise a first gallium-containing precursor and a second indium containing precursor.

### EMBODIMENT 24

The method of any one of Embodiments 18 through 23, wherein forming InGaN comprises growing the InGaN on a substrate within the chamber at a growth rate of at least about 5.0 Angstroms per second.

### EMBODIMENT 25

The method of any one of Embodiments 18 through 24, wherein forming InGaN comprises forming the InGaN on GaN.

### EMBODIMENT 26

The method of Embodiment 25, wherein forming InGaN further comprises forming the InGaN to have a defect density at least substantially equal to or less than a defect density of the GaN.

### EMBODIMENT 27

The method of any one of Embodiments 18 through 26, wherein forming InGaN comprises forming a layer of InGaN having an average layer thickness of at least about 0.5 micron.

### EMBODIMENT 28

A method of forming InGaN, comprising: applying microwave energy to at least one nitrogen-containing precursor and heating the at least one nitrogen-containing precursor to at least partially decompose the at least one nitrogen-containing precursor to form nitrogen ions; decomposing at least one Group III precursor to form indium ions and gallium ions; and forming InGaN in a chamber from the nitrogen ions, the indium ions, and the gallium ions at a growth rate of at least about 1.0 Angstroms per second.

### EMBODIMENT 29

The method of Embodiment 28, wherein heating the at least one nitrogen-containing precursor comprises flowing the at least one nitrogen-containing precursor through a heated metal diffuser.

### EMBODIMENT 30

The method of Embodiment 29, wherein flowing the at least one nitrogen-containing precursor through the heated metal diffuser comprises exposing the at least one nitrogen-containing precursor to at least one catalyst and catalyzing decomposition of the at least one nitrogen-containing precursor within the heated diffuser.

### EMBODIMENT 31

The method of any one of Embodiments 28 through 30, wherein applying microwave energy to the at least one nitrogen-containing precursor comprises generating a plasma in an enclosure separate from the chamber using the microwave energy, and passing the at least one nitrogen-containing precursor through the enclosure to form nitrogen radicals therein.

The example embodiments of the disclosure described above do not limit the scope of the invention, since these embodiments are merely examples of embodiments of the invention, which is defined by the scope of the appended claims and their legal equivalents. Any equivalent embodiments are intended to be within the scope of this invention. Indeed, various modifications of the disclosure, in addition to those shown and described herein, such as alternate useful combinations of the elements described, will become apparent to those skilled in the art from the description. In other words, one or more features of one example embodiment described herein may be combined with one or more features of another example embodiment described herein to provide additional embodiments of the disclosure. Such modifications and embodiments are also intended to fall within the scope of the appended claims.

What is claimed is:

1. A method of forming InGaN, comprising:
heating and at least partially decomposing at least one nitrogen-containing precursor in a heated diffuser to form nitrogen ions;
at least partially decomposing at least one Group III precursor to form indium ions and gallium ions; and
forming InGaN from the nitrogen ions, the indium ions, and the gallium ions within a chamber at a growth rate of at least about 1.0 Angstroms per second.

2. The method of claim 1, wherein heating and at least partially decomposing the at least one nitrogen-containing precursor in the heated diffuser comprises flowing the at least one nitrogen-containing precursor through a heated diffuser comprising a metal.

3. The method of claim 2, wherein flowing the at least one nitrogen-containing precursor through the heated diffuser comprising the metal comprises flowing the at least one nitrogen-containing precursor through a heated steel diffuser.

4. The method of claim 2, wherein flowing the at least one nitrogen-containing precursor through the heated diffuser comprising the metal comprises exposing the at least one nitrogen-containing precursor to at least one catalyst and catalyzing decomposition of the at least one nitrogen-containing precursor within the heated diffuser.

5. The method of claim 4, wherein exposing the at least one nitrogen-containing precursor to the at least one metal catalyst comprises exposing the at least one nitrogen-containing precursor to at least one of nickel and iron.

6. The method of claim 1, further comprising flowing heated fluid through the diffuser to heat the diffuser.

7. The method of claim 6, further comprising isolating the at least one nitrogen-containing precursor from the heated fluid flowing through the diffuser.

8. The method of claim 6, wherein flowing heated fluid through the diffuser comprises flowing oil through the diffuser.

9. The method of claim 6, wherein flowing heated fluid through the diffuser comprises flowing fluorinated liquid through the diffuser.

10. The method of claim 1, wherein heating and at least partially decomposing the at least one nitrogen-containing precursor in the heated diffuser comprises heating the at least one nitrogen-containing precursor in the heated diffuser to a temperature between about 60° C. and about 215° C. and injecting the heated at least one nitrogen-containing precursor into the chamber at the temperature between about 60° C. and about 215° C.

11. The method of claim 1, further comprising selecting the at least one nitrogen-containing precursor to comprise ammonia.

12. The method of claim 1, further comprising selecting the at least one Group III precursor to comprise a first gallium-containing precursor and a second indium-containing precursor.

13. The method of claim 1, wherein forming InGaN comprises forming InₓGa_{y}N, wherein x+y is about equal to 1, and wherein x is between about 0.05 and about 0.15.

14. The method of claim 1, wherein foliating InGaN comprises growing the InGaN on a substrate within the chamber at a growth rate of at least about 5.0 Angstroms per second.

15. The method of claim 1, wherein forming InGaN comprises forming the InGaN on GaN.

16. The method of claim 15, wherein forming InGaN further comprises forming the InGaN to have a defect density at least substantially equal to or less than a defect density of the GaN.

17. The method of claim 1, wherein forming InGaN comprises forming a layer of InGaN having an average layer thickness of at least about 0.5 micron.

18. A method of forming InGaN, comprising:
applying microwave energy to at least one nitrogen-containing precursor and decomposing the at least one nitrogen-containing precursor to form nitrogen ions;
decomposing at least one Group III precursor to form indium ions and gallium ions; and
forming InGaN in a chamber from the nitrogen ions, the indium ions, and the gallium ions at a growth rate of at least about 1.0 Angstroms per second.

19. The method of claim 18, wherein applying microwave energy to the at least one nitrogen-containing precursor and decomposing the at least one nitrogen-containing precursor to form nitrogen ions comprises forming nitrogen radicals.

20. The method of claim 18, further comprising applying the microwave energy to the at least one nitrogen-containing precursor without applying the microwave energy to the at least one Group III precursor.

21. The method of claim 18, wherein applying microwave energy to the at least one nitrogen-containing precursor comprises generating a plasma in an enclosure separate from the chamber using the microwave energy, and passing the at least one nitrogen-containing precursor through the enclosure.

22. The method of claim 18, further comprising selecting the at least one nitrogen-containing precursor to comprise ammonia.

23. The method of claim 18, further comprising selecting the at least one Group III precursor to comprise a first gallium-containing precursor and a second indium containing precursor.

24. The method of claim 18, wherein forming InGaN comprises growing the InGaN on a substrate within the chamber at a growth rate of at least about 5.0 Angstroms per second.

25. The method of claim 18, wherein forming InGaN comprises forming the InGaN on GaN.

26. The method of claim 18, wherein foaming InGaN further comprises forming the InGaN to have a defect density at least substantially equal to or less than a defect density of the GaN.

27. The method of claim 18, wherein forming InGaN comprises forming a layer of InGaN having an average layer thickness of at least about 0.5 micron.

28. A method of forming InGaN, comprising:
applying microwave energy to at least one nitrogen-containing precursor and heating the at least one nitrogen-containing precursor to at least partially decompose the at least one nitrogen-containing precursor to form nitrogen ions;
decomposing at least one Group III precursor to form indium ions and gallium ions; and
forming InGaN in a chamber from the nitrogen ions, the indium ions, and the gallium ions at a growth rate of at least about 1.0 Angstroms per second.

29. The method of claim 28, wherein heating the at least one nitrogen-containing precursor comprises flowing the at least one nitrogen-containing precursor through a heated metal diffuser.

30. The method of claim 29, wherein flowing the at least one nitrogen-containing precursor through the heated metal diffuser comprises exposing the at least one nitrogen-containing precursor to at least one catalyst and catalyzing decomposition of the at least one nitrogen-containing precursor within the heated diffuser.

31. The method of claim 30, wherein applying microwave energy to the at least one nitrogen-containing precursor comprises generating a plasma in an enclosure separate from the chamber using the microwave energy, and passing the at least one nitrogen-containing precursor through the enclosure to form nitrogen radicals therein.
